(19) United States
(12) Patent Application Publication
(10) Pub. No.: US 2024/0250372 A1
(43) Pub. Date: Jul. 25, 2024

(54) BATTERY PACK AND WEARABLE DEVICE

(71) Applicant: MURATA MANUFACTURING CO., LTD., Kyoto (JP)

(72) Inventor: Hiromitsu SENNAMI, Kyoto (JP)

(21) Appl. No.: 18/610,738

(22) Filed: Mar. 20, 2024

Related U.S. Application Data
(63) Continuation of application No. PCT/JP2022/033425, filed on Sep. 6, 2022.

(30) Foreign Application Priority Data
Oct. 14, 2021 (JP) 2021-169051

(51) Int. Cl. H01M 50/284; H01M 10/42; H01M 50/202; H01M 50/247; H04R 1/10; H05K 1/02

(52) U.S. Cl. CPC H01M 50/284; H01M 10/425; H01M 50/202; H01M 50/247; H04R 1/1025; H04R 1/1041; H05K 1/0271; H05K 1/028; H01M 2220/30; H04R 2420/07; H05K 2201/10037

(57) ABSTRACT

Provided is a battery pack including: a battery including an electrode portion and having a cylindrical shape; and a circuit board disposed on a circumferential side surface of the battery, in which the circuit board includes a circuit component mounting portion and a wiring part, the circuit component mounting portion includes a reinforcing portion, and the wiring part includes a flexible printed substrate.

### CROSS REFERENCE TO RELATED APPLICATIONS

The present application is a continuation of PCT patent application no. PCT/JP2022/033425, filed on Sep. 6, 2022, which claims priority to Japanese patent application no. 2021-169051, filed on Oct. 14, 2021, the entire contents of which are incorporated herein by reference.

### BACKGROUND

The present disclosure relates to a battery pack and a wearable device.

There have been proposed electronic devices using flexible printed circuits (may be referred to as FPCs). For example, a technique for improving a volume mounting density by bending a flexible printed substrate on which components are mounted.

Further, for example, a technique for enhancing mounting strength by a configuration in which a reinforcing plate is provided on a flexible printed substrate.

A coin-shaped battery, for example, that enables a compact configuration by a configuration in which a flexible printed substrate is routed around a peripheral surface.

### SUMMARY

The present disclosure relates to a battery pack and a wearable device.

Meanwhile, application of a battery pack using a secondary battery is also expanding to small devices (also referred to as hearable devices) such as wireless earphones. In this field, it is required to reduce the height of the entire battery pack in order to suppress an increase in size of the device. The techniques described above in Background section lack a viewpoint related to height reduction. Specifically, since components are arranged in a thickness direction, it is difficult to reduce a height of an electronic component.

Therefore, the present disclosure relates to providing, in an embodiment, a battery pack and a wearable device having a configuration capable of reducing a height.

The present disclosure provides, in an embodiment, a battery pack including: a battery including an electrode portion and having a cylindrical shape; and a circuit board disposed on a circumferential side surface of the battery, in which the circuit board includes a circuit component mounting portion and a wiring part, the circuit component mounting portion includes a circuit component mounted on one main surface side of the circuit board and a reinforcing portion mounted on the other main surface side of the circuit board, and the wiring part includes a flexible printed substrate.

According to an embodiment, it is possible to reduce the height of a battery pack and a wearable device to which the battery pack is applied. Note that, the contents of the present disclosure are not to be construed as being limited by the effects exemplified in the present description.

### BRIEF DESCRIPTION OF THE FIGURES

FIG. 1 is a diagram referred to in the description of problems to be considered in the present disclosure.

FIG. 2 is a diagram referred to in the description of problems to be considered in the present disclosure.

FIG. 3 is a diagram referred to in the description of problems to be considered in the present disclosure.

FIG. 4 is a diagram referred to in the description of an outline of the present disclosure.

FIG. 5 is a diagram referred to in the description of the outline of the present disclosure.

FIG. 6 is a diagram for describing an example of a battery.

FIG. 7 is a diagram for describing an example of a circuit board.

FIG. 8 is a diagram for describing an example of the circuit board.

FIG. 9 is a diagram for describing an example of the circuit board.

FIG. 10 is a diagram for describing an example of a battery holder.

FIG. 11 is a diagram for describing an example of the battery holder.

FIG. 12 is a diagram for describing an example of a battery pack according to an embodiment.

FIG. 13 is a diagram for describing an example of the battery pack according to an embodiment.

FIG. 14 is a diagram for describing an example of the battery pack according to an embodiment.

FIG. 15 is a diagram for describing an example of the battery pack according to an embodiment.

FIG. 16 is a diagram for describing an example of a battery pack according to an embodiment.

FIG. 17 is a diagram referred to in the description of problems to be considered in an embodiment.

FIG. 18 is a diagram for describing an example of a battery pack according to an embodiment.

FIG. 19 is a diagram for describing a modification example.

FIG. 20 is a diagram for describing an application example of an embodiment.

FIG. 21 is a diagram for describing an application example of an embodiment.

### DETAILED DESCRIPTION

The present disclosure will be described below in further detail include with reference to the drawings according to an embodiment.

Examples of the present disclosure are described below according to an embodiment, and the contents of the present disclosure are not limited thereto.

Unless otherwise described, the present disclosure is not intended to be limited to only dimensions, materials, and shapes of constituent members described in the embodiments, relative arrangements thereof, and descriptions of directions such as upward, downward, left, and right and the like, which are merely illustrative examples. Note that, sizes, positional relationships, and the like of the members illustrated in the drawings may be exaggerated for clarity of description, and, only some of the reference numerals may be illustrated, or a part of an illustration may be simplified, in order to prevent the illustration from being complicated. Furthermore, in the following description, the same names and reference numerals indicate the same or similar members, and redundant descriptions will be appropriately omitted.

First, in order to facilitate understanding of the present disclosure, an outline of the present disclosure will be described while referring to problems to be considered.

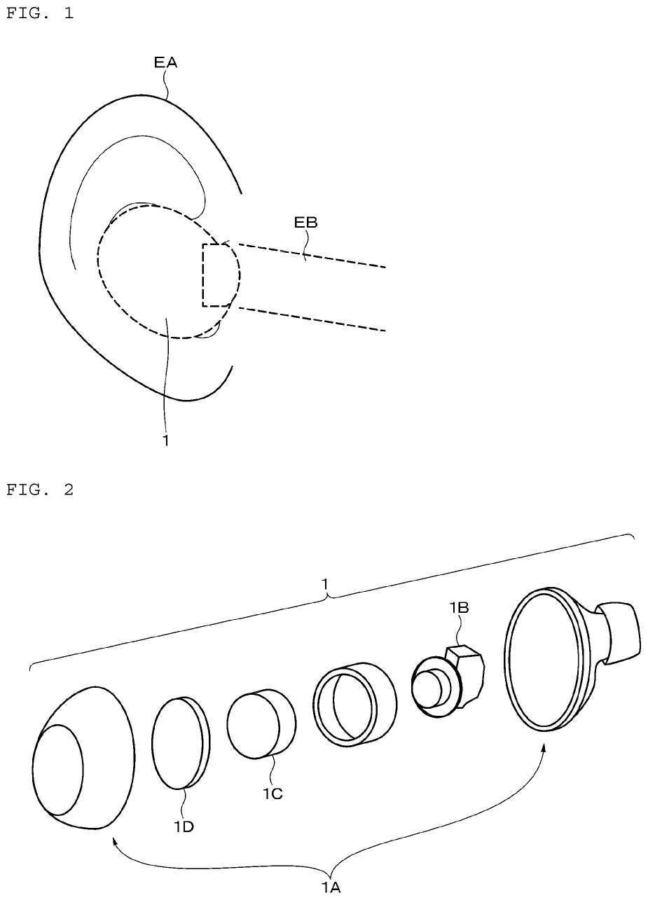

As described above, a battery pack including a secondary battery such as a lithium ion battery has expanded its application field not only to large devices such as vehicles but also to small devices. Here, problems to be considered will be described with reference to FIGS. 1 to 3 while exemplifying a wireless earphone, which is one of hearable devices, as a specific example of the small device.

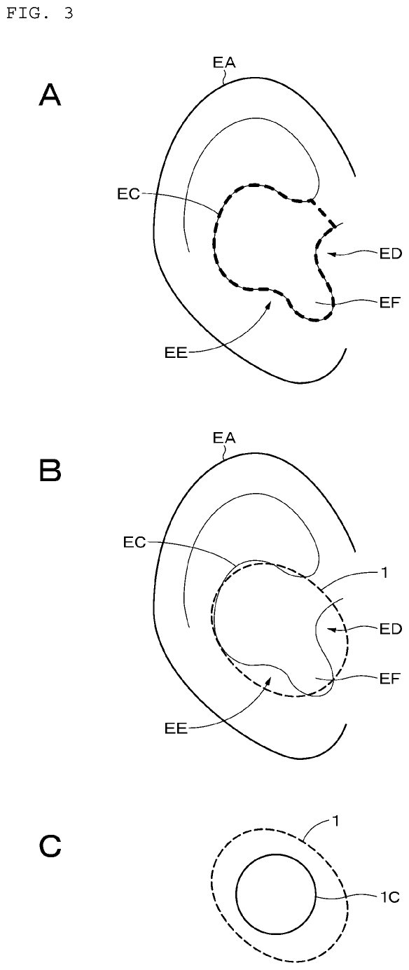

FIG. 1 illustrates a state in which a wireless earphone (wireless earphone 1) according to the present example is worn on a human ear EA. FIG. 2 is an exploded perspective view of the wireless earphone 1. FIG. 3A is a diagram for describing the shape of the ear EA, FIG. 3B is a diagram for describing how to support the wireless earphone 1 by the ear EA, and FIG. 3C is a diagram schematically illustrating the battery pack housed in the wireless earphone 1.

As illustrated in FIG. 2, the wireless earphone 1 schematically includes a housing 1A, a driver unit 1B housed in the housing 1A, a battery pack 1C housed in the housing 1A, and a circuit board 1D housed in the housing 1A. As illustrated in FIG. 1, the wireless earphone 1 is mounted such that a sound emission direction of the driver unit 1B faces an ear canal EB. A sound is reproduced by applying an electric signal to the driver unit 1B, and the sound is transmitted to an eardrum (not illustrated) via the ear canal EB. In order to effectively transmit sound, a built-in component housed in the housing 1A is disposed so as to face the ear canal EB.

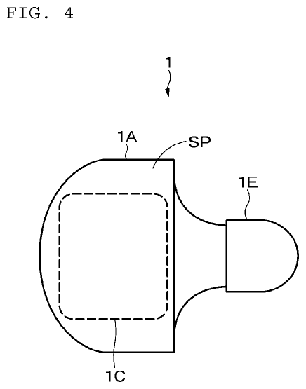

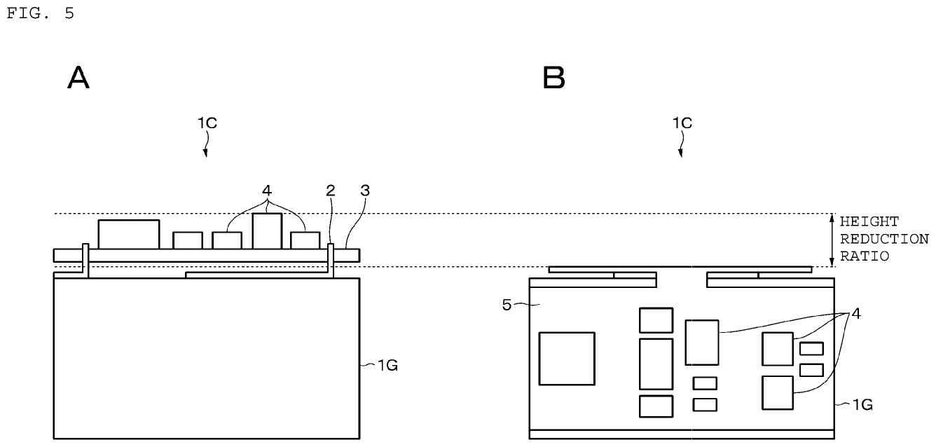

As illustrated in FIG. 3A, the ear EA includes a concha EC, a tragus ED, an antitragus EE, and an intertragic notch EF. As illustrated in FIG. 3B, the wireless earphone 1 is worn so that the housing 1A is accommodated in the concha, and the housing 1A is supported by the tragus ED, the antitragus EE, and the intertragic notch EF. In order to facilitate such mounting, as illustrated in FIG. 4, the shape of the housing 1A of the wireless earphone 1 is often an elliptical shape. If at least the height of the housing 1A (length along the sound radiation direction) is not within an antihelix, the balance is poor, which causes discomfort at the time of wearing or causes the wireless earphone 1 to easily come off due to a body shake during exercise. Thus, it is required to reduce the height of the built-in component built in the housing 1A. That is, it is required to reduce the height of the battery pack 1C, which is a built-in component built in the housing 1A.

FIG. 4 illustrates an appearance example of the wireless earphone 1. In consideration of adhesion to the ear EA and storability into the ear EA, the housing 1A of the wireless earphone 1 often spreads in a mortar shape from an ear piece 1E inserted into the ear canal EB toward the opposite side. When the battery pack 1C having a small cylindrical shape (slightly thick coin shape) is housed in the housing 1A, as schematically shown in FIG. 4, an extra space SP is generated between an inner wall of the housing 1A and a side surface of the battery pack 1C.

Thus, in the present disclosure, in order to reduce the height of the battery pack, a circuit component (for example, a protection integrated circuit (IC) that performs control for ensuring safety of the battery pack or a field effect transistor (FET) for charge and discharge control) applied to the battery pack is mounted on a flexible printed substrate having flexibility. The flexible printed substrate is disposed on a circumferential side surface side of the battery, and the circuit component mounted on the flexible printed substrate is disposed in the extra space SP. The flexible printed substrate means a thin flexible printed wiring board having flexibility. In general, the flexible printed substrate has a structure in which an adhesive layer and a conductor foil such as a copper foil are bonded onto a base film which is a thin-film insulator using polyimide and the like. A predetermined circuit pattern is formed on the flexible printed substrate by the conductor foil.

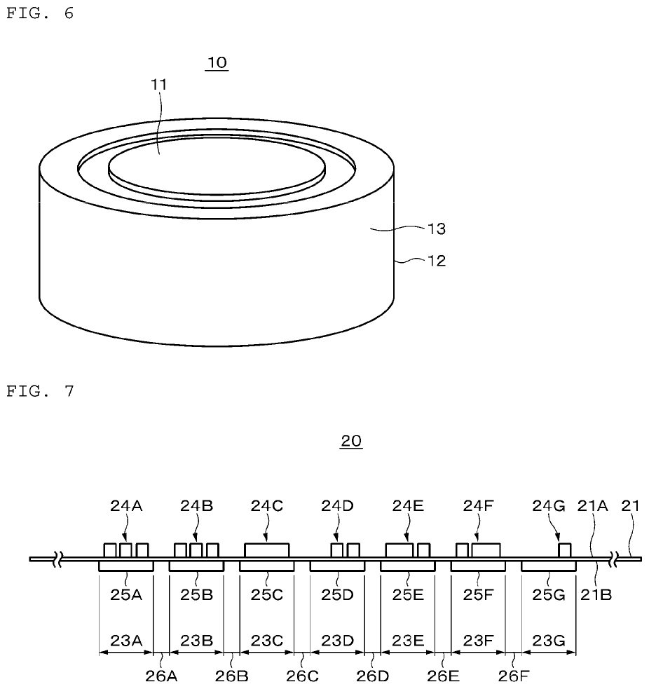

Accordingly, the height of the battery pack can be reduced. FIG. 5A illustrates an example in which a circuit board 3 (for example, the circuit board 1D described above) is connected to an upper surface of a battery 1G, not a side surface of the battery 1G, via a relay tab 2. A circuit component 4 is mounted on the circuit board 3. In the configuration illustrated in FIG. 5A, since the circuit component 4 is disposed on an upper side of the battery 1G, a thickness (length in up-down direction in FIGS. 5A and 5B) of the battery pack 1C increases. Thus, as shown in FIG. 5B, in the present disclosure, schematically, a flexible printed substrate 5 on which the circuit component 4 is mounted is disposed on the circumferential side surface (circumferential side surface 13 to be described later) of the battery 1G. Accordingly, the height of the battery pack 1C can be reduced.

When a circuit component is mounted on the flexible printed substrate having flexibility, the strength of the flexible printed substrate is weak, and there is a possibility that mechanical stress such as bending occurs in the circuit component and a solder joint; therefore, it is common to attach a flat plate-shaped laminate or a metal plate to a back surface (opposite surface) of a region where the circuit component is mounted to reinforce the flexible printed substrate. When the flexible printed substrate to which the reinforcing plate is attached is bent to be disposed on the circumferential side surface, local stress is generated, and there is a possibility that the circuit component is peeled off from the flexible printed substrate. The present disclosure also addresses such problems. Hereinafter, the present disclosure will be described below in further detail according to an embodiment.

A battery pack (hereinafter appropriately referred to as the battery pack 100) according to a first embodiment includes the battery 10, the circuit board 20 disposed on the circumferential side surface 13 of the battery 10, and a battery holder 30 attached to the battery 10. First, each configuration will be described, and then a configuration example of the battery pack 100 including them will be described.

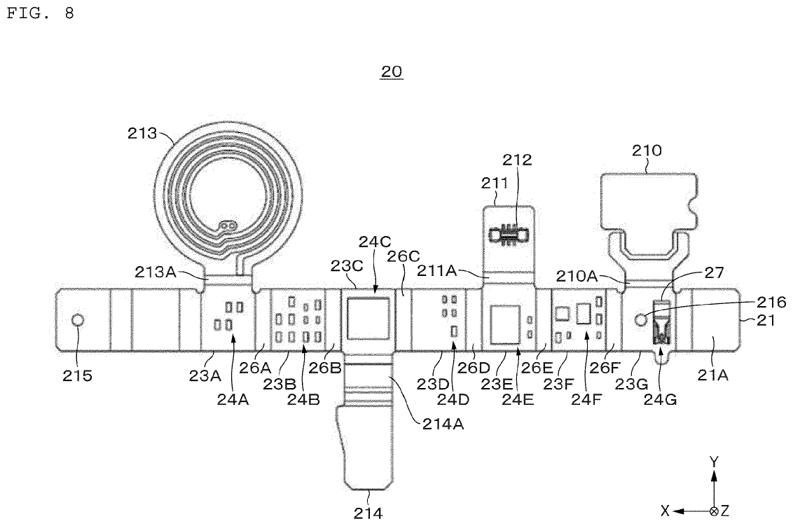

FIG. 6 illustrates an appearance of the battery 10 according to the first embodiment. The battery 10 is, for example, a coin-type secondary battery (for example, a lithium ion battery) having a substantially cylindrical shape as a whole and having the circumferential side surface 13. A peripheral surface of the battery 10 is made of, for example, stainless steel whose surface is nickel-plated. A part of the peripheral surface of the battery 10 is a positive electrode terminal, and the other part of the peripheral surface is a negative electrode terminal. In the present embodiment, a positive electrode terminal 11 is provided on a part of an upper surface of the battery 10. A portion other than the positive electrode terminal 11 in the battery 10, for example, the circumferential side surface 13 or the bottom surface of the battery 10 has a negative polarity, and functions as a negative electrode terminal 12. The positive electrode terminal 11 and the negative electrode terminal 12 are insulated from each other. The location of the positive electrode terminal 11 and the location of the negative electrode terminal 12 may be opposite to each other.

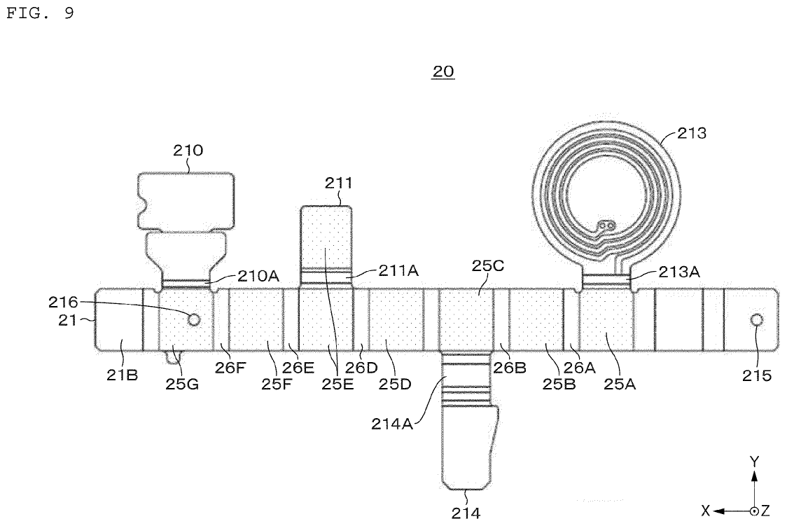

Next, an example of the circuit board 20 will be described with reference to FIGS. 7 to 9. As illustrated in FIG. 7, the circuit board 20 includes, for example, a flexible printed substrate 21 made of a polyimide film or the like. The flexible printed substrate 21 may be a single-sided substrate, a double-sided substrate, or a multilayer substrate. The flexible printed substrate 21 has a front surface 21A which is an example of one main surface and a back surface 21B which is the other main surface.

The circuit board 20 includes a circuit component mounting portion which is a region where a circuit component is mounted on the front surface 21A of the flexible printed substrate 21. As illustrated in FIG. 7, the circuit board 20 includes, for example, seven circuit component mounting portions 23A to 23G separated from each other. In a case where it is not necessary to distinguish the individual circuit component mounting portions, the circuit component mounting portions are appropriately collectively referred to as the circuit component mounting portion 23. A circuit component is mounted on the front surface 21A side of the circuit component mounting portion 23. For example, a circuit component 24A including one or a plurality of circuit components is mounted on the front surface 21A side of the circuit component mounting portion 23A. Similarly, circuit components 24B to 24G are also mounted on the corresponding circuit component mounting portions in the other circuit component mounting portions. In a case where it is not necessary to distinguish the individual circuit components, the circuit components are appropriately collectively referred to as the circuit component 24. In the circuit component 24, the circuit components are electrically connected to each other by a pattern of copper foil formed on the flexible printed substrate 21, and the circuit component 24 is electrically connected to an electrode portion (the positive electrode terminal 11 or the negative electrode terminal 12) of the battery 10 as appropriate. As the circuit component 24 mounted on the flexible printed substrate 21, an IC, a resistor, a capacitor, a connection terminal (connector), and the like for protecting the battery 10 can be exemplified.

The circuit component mounting portion 23 has a reinforcing portion provided on the back surface 21B side. For example, the circuit component mounting portion 23 includes, for example, a reinforcing portion 25A provided on the back surface 21B side of the circuit component mounting portion 23A. Similarly, the circuit component mounting portion 23 includes reinforcing portions 25B to 25G provided on the back surface 21B side of the other circuit component mounting portions. In a case where it is not necessary to distinguish the individual reinforcing portions, the reinforcing portions are appropriately collectively referred to as the reinforcing portion 25. The reinforcing portion 25 is attached to the back surface 21B side of the circuit component mounting portion 23 by an appropriate method such as adhesion.

The reinforcing portion 25 is, for example, a thin plate-shaped member that covers the back surface 21B side of the circuit component mounting portion 23. Examples of the material of the reinforcing portion 25 include a glass epoxy resin, a polyimide resin, a metal such as stainless steel, and a combination thereof. Among them, the glass epoxy resin is preferable as the material of the reinforcing portion 25. This is because the glass epoxy resin is inexpensive and easy to mold. As described later, the reinforcing portion 25 may be in contact with or face the circumferential side surface 13 of the battery 10. In this case, when metal is used as the reinforcing portion 25, it is necessary to devise a circuit pattern of the flexible printed substrate 21 in order to ensure insulation. On the other hand, when a glass epoxy resin is used as the reinforcing portion 25, insulation can be secured, so that it is not necessary to devise a circuit pattern, and a manufacturing process can be simplified.

The circuit board 20 further includes a wiring part. For example, the circuit board 20 includes wiring parts 26A, 26B, . . . , and 26F. In a case where it is not necessary to distinguish the individual wiring parts, the wiring parts are appropriately collectively referred to as the wiring part 26. The wiring part 26 couples the plurality of circuit component mounting portions 23 to each other. For example, the wiring part 26A couples the circuit component mounting portion 23A and the circuit component mounting portion 23B to each other. The wiring part 26B couples the circuit component mounting portion 23B and the circuit component mounting portion 23C to each other. The wiring part 26C couples the circuit component mounting portion 23C and the circuit component mounting portion 23D to each other. The wiring part 26D couples the circuit component mounting portion 23D and the circuit component mounting portion 23E to each other. The wiring part 26E couples the circuit component mounting portion 23E and the circuit component mounting portion 23F to each other. The wiring part 26F couples the circuit component mounting portion 23F and the circuit component mounting portion 23G to each other.

The wiring part 26 according to the present embodiment includes the flexible printed substrate 21. That is, in the present embodiment, the circuit component mounting portion 23 and the wiring part 26 are configured by the integrated flexible printed substrate 21. A predetermined circuit pattern is patterned in the wiring part 26. The circuit components are electrically connected to each other by this circuit pattern, and the circuit component 24 is electrically connected to the electrode portion (the positive electrode terminal 11 or the negative electrode terminal 12) of the battery 10 as appropriate.

The reinforcing portion 25 described above may be a thin plate-shaped member that covers in part, instead of as a whole, the back surface 21B side of the circuit component mounting portion 23. The size of the circuit component mounting portion 23, the number of circuit components included in each of the circuit component mounting portions 23, and the like can be changed as appropriate. Intervals (that is, a length of the wiring part (length of the wiring part along a plane direction of the flexible printed substrate 21)) between the circuit component mounting portions 23 are not necessarily equal.

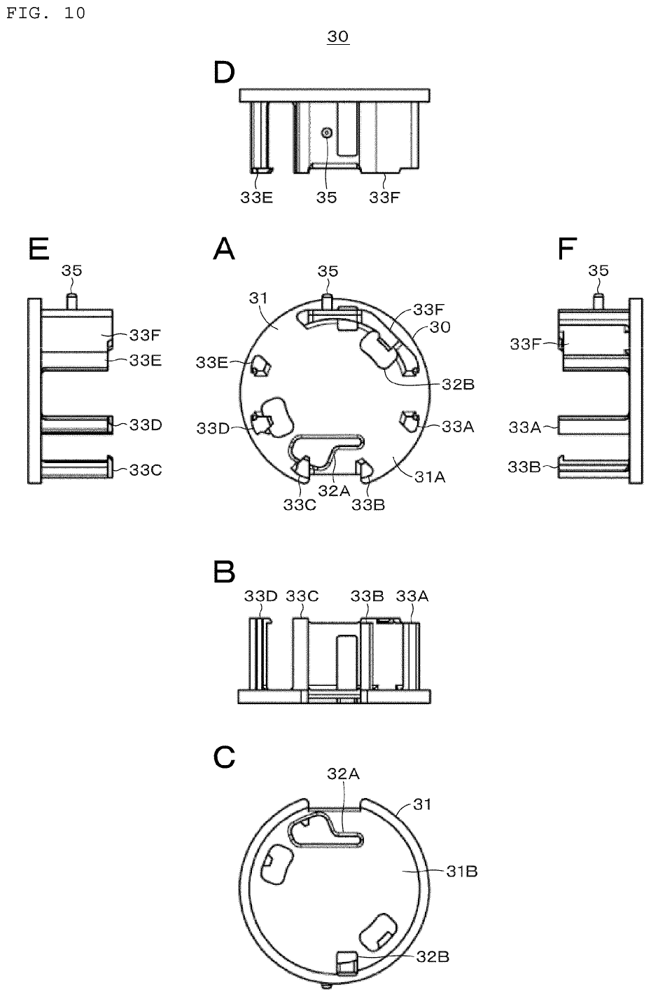

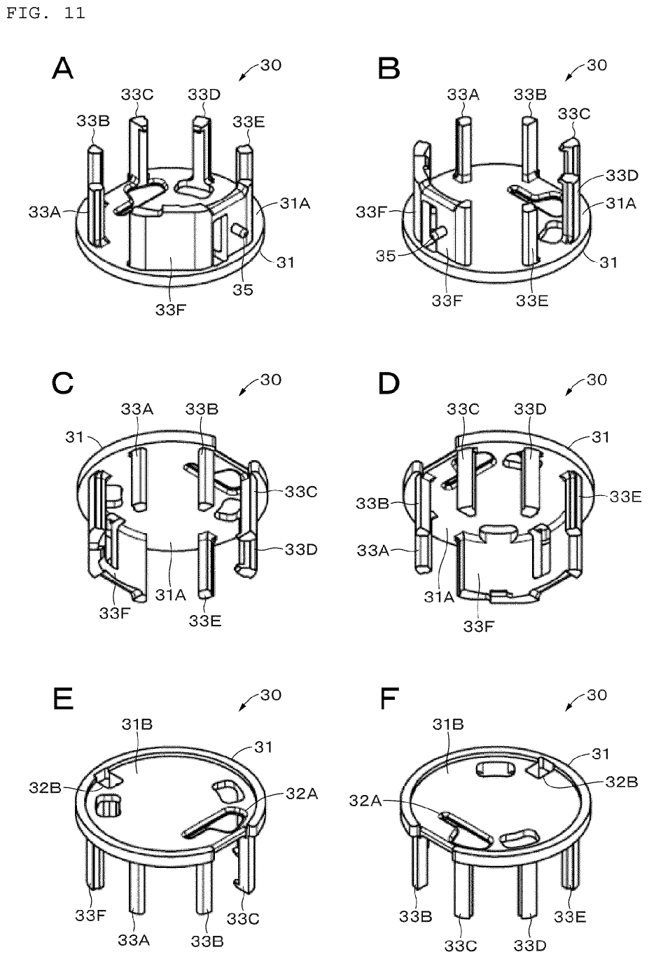

A detailed configuration example of the circuit board 20 will be described with reference to FIGS. 8 and 9. FIG. 8 is a diagram of the circuit board 20 as viewed from the front surface 21A side. FIG. 9 is a diagram in which the circuit board 20 illustrated in FIG. 8 is turned over and the circuit board 20 is viewed from the back surface 21B side. In FIGS. 8 and 9, a longitudinal direction of the flexible printed substrate 21 is an X axis, a lateral direction of the flexible printed substrate 21 is a Y axis, and a thickness direction of the flexible printed substrate 21 is a Z axis.

As described above, the circuit board 20 includes the seven circuit component mounting portions 23. The circuit component 24 is mounted on the front surface 21A of the circuit component mounting portion 23.

A positive electrode connection terminal 210 extends in a +Y axis direction from the circuit component mounting portion 23G. The positive electrode connection terminal 210 is formed from, for example, a metal foil, and is coupled to the circuit component mounting portion 23G via a boundary portion 210A which is a part of the flexible printed substrate 21. The positive electrode connection terminal 210 is connected to the positive electrode terminal 11 by bending the boundary portion 210A toward the front side (−Z axis direction). The positive electrode connection terminal 210 is connected to a positive electrode side of a positive and negative electrode external terminal 212 described later via a predetermined circuit pattern.

An output terminal arrangement portion 211 extends in the +Y axis direction from the circuit component mounting portion 23E. The output terminal arrangement portion 211 is coupled to the circuit component mounting portion 23E via a boundary portion 211A. The output terminal arrangement portion 211 and the boundary portion 211A constitute a part of the flexible printed substrate 21. The output terminal arrangement portion 211 is provided with the positive and negative electrode external terminal 212 which is a connector for taking out an output of the battery 10 connected to the flexible printed substrate 21. The positive and negative electrode external terminal 212 can also be used as a terminal when inputting (charging) to the battery 10. The boundary portion 211A is bent, for example, toward a depth side (+Z axis direction). As a result, the positive and negative electrode external terminal 212 is located on the side opposite to the circuit component 24.

A wireless power supply portion 213 extends from the circuit component mounting portion 23A in the +Y axis direction. The wireless power supply portion 213 has a configuration in which a coil pattern is mounted on a substantially circular flexible printed substrate forming a part of the flexible printed substrate 21. The wireless power supply portion 213 is coupled to the circuit component mounting portion 23A via a boundary portion 213A. The boundary portion 213A is bent toward the front side (−Z axis direction). Specifically, after the positive electrode connection terminal 210 is electrically connected to the positive electrode terminal 11, the wireless power supply portion 213 is disposed on an upper surface of the positive electrode connection terminal 210 by bending the boundary portion 213A toward the front side (−Z axis direction).

A heat dissipation pad 214 extends from the circuit component mounting portion 23C in the −Y axis direction. The heat dissipation pad 214 is coupled to the circuit component mounting portion 23C via a boundary portion 214A. The boundary portion 214A is bent toward the front side (−Z axis direction).

A through hole 215 is formed at an end (for example, a left end in FIG. 8) of the flexible printed substrate 21. A through hole 216 is also formed in the circuit component mounting portion 23G. The through hole 215 and the through hole 216 are hole portions into which a protrusion for positioning the flexible printed substrate 21 is inserted.

As illustrated in FIG. 9, a reinforcing portion 25E includes two reinforcing portions adjacent to each other via the boundary portion 211A. Therefore, the circuit board 20 has eight reinforcing portions 25. In FIG. 9, dots are attached to locations of the reinforcing portions 25.

A spring terminal 27 is mounted at a predetermined position of the circuit component mounting portion 23G. Although described in detail later, the spring terminal 27 functions as a negative electrode connection terminal that is in contact with (abuts against) the circumferential side surface 13 of the battery 10. A circuit pattern electrically connected to the spring terminal 27 is formed at a position where the spring terminal 27 is disposed in the circuit component mounting portion 23G. The circuit pattern is connected to the negative electrode side of the positive and negative electrode external terminal 212. In the present example, the circuit component 24G corresponds to the spring terminal 27.

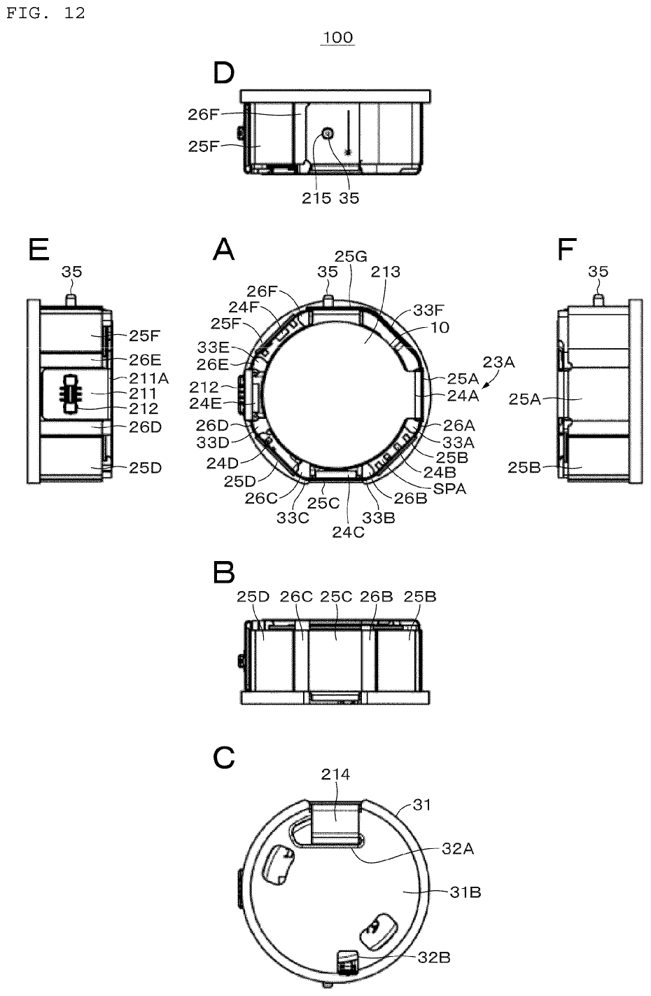

Next, an example of the battery holder 30 will be described with reference to FIGS. 10 and 11. FIG. 10A is a top view of the battery holder 30, FIG. 10B is a front view of the battery holder 30, FIG. 10C is a bottom view of the battery holder 30, FIG. 10D is a rear view of the battery holder 30, FIG. 10E is a left side view of the battery holder 30, and FIG. 10F is a right side view of the battery holder 30. FIGS. 11A to 11F are perspective views of the battery holder 30 as viewed from different directions.

The battery holder 30 is formed of, for example, resin. The battery holder 30 includes a circular base 31. The base 31 has one main surface 31A and the other main surface 31B. A hole portion 32A and a hole portion 32B penetrating the base 31 are formed in the base 31.

A columnar member is erected from the vicinity of a peripheral edge of the main surface 31A of the base 31. For example, columnar members 33A, 33B, . . . , 33E having a columnar shape and a columnar member 33F having a wall shape are erected. In the present embodiment, the columnar members are provided at substantially equal intervals; however, the present disclosure is not limited thereto. The number and arrangement of the columnar members can be arbitrary. The battery 10 is disposed so as to be placed on the main surface 31A of the base 31 and located inside the columnar members 33A to 33F. In a case where it is not necessary to distinguish the individual columnar members, the columnar members are appropriately collectively referred to as the columnar members 33.

A protrusion 35 protruding outward is provided from a predetermined portion of the columnar member 33F. The protrusion 35 is a protrusion inserted into the through hole 215 and the through hole 216.

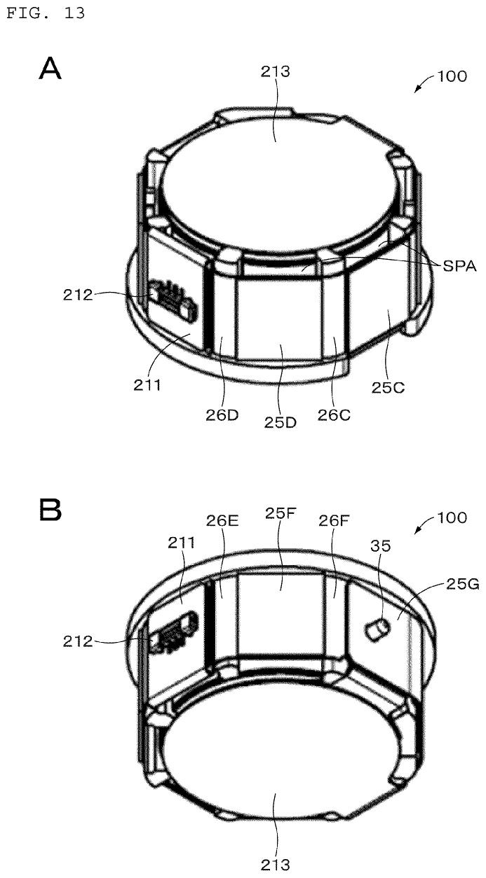

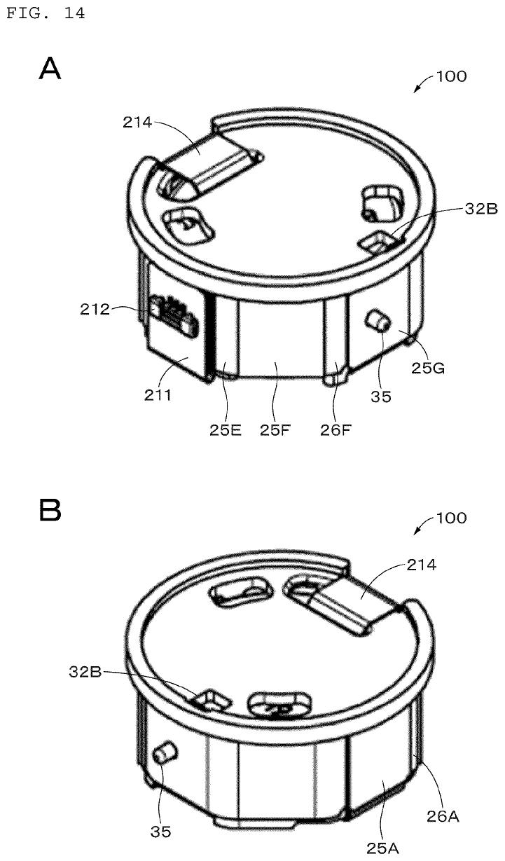

The battery pack 100 including the battery 10, the circuit board 20, and the battery holder 30 described above will be described with reference to FIGS. 12, 13, and 14. FIG. 12A is a top view of the battery pack 100, FIG. 12B is a front view of the battery pack 100, FIG. 12C is a bottom view of the battery pack 100, FIG. 12D is a rear view of the battery pack 100, FIG. 12E is a left side view of the battery pack 100, and FIG. 12F is a right side view of the battery pack 100. FIGS. 13A, 13B, 14A, and 14B are perspective views of the battery pack 100 as viewed from different directions.

The battery 10 is disposed inside the columnar member 33. For example, the circumferential side surface 13 of the battery 10 is abutted against the inside of the columnar member 33. Thus, the battery 10 is supported by the columnar member 33.

The circuit board 20 is disposed so as to be wound around the outside of the columnar member 33. As a result, the circuit component 24 is disposed in a facing gap SPA between the circumferential side surface 13 of the battery 10 and the surface 21A of the flexible printed substrate 21. That is, the circuit component 24 and the circumferential side surface 13 face each other. The reinforcing portion 25 of the circuit board 20 is disposed so as to face outward. The positive and negative electrode external terminal 212 is disposed outside the circuit component mounting portion 23E. The wireless power supply portion 213 is disposed on the upper surface of the battery 10.

The wiring part 26 is in contact with the outside of the columnar member 33. Specifically, the wiring part 26A is in contact with the outside of the columnar member 33A. The wiring part 26B is in contact with the outside of the columnar member 33B. The wiring part 26C is in contact with the outside of the columnar member 33C. The wiring part 26D is in contact with the outside of the columnar member 33D. The wiring part 26E is in contact with the outside of the columnar member 33E. The wiring part 26F is in contact with the outside (part of the outside) of the columnar member 33F.

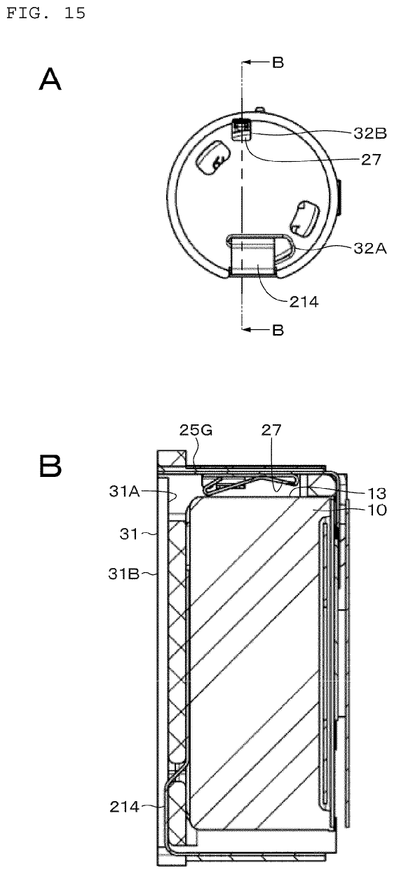

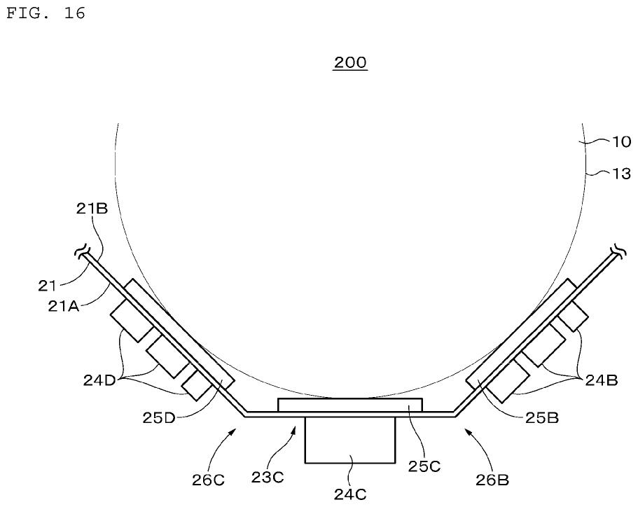

Next, a detailed configuration example of the battery pack 100 will be described while describing an example of a method of manufacturing the battery pack 100 with reference to FIG. 15 in addition to FIGS. 12 to 14. FIG. 15A is a view of the battery pack 100 viewed from the main surface 31B of the base 31, and FIG. 15B is a cross-sectional view of the battery pack 100 taken along a cutting line B-B in FIG. 15A.

First, the through hole 215 of the flexible printed substrate 21 is inserted through the protrusion 35. Then, the circuit board 20 is bent so as to be wound around the outside of the columnar member 33. At this time, the circuit board 20 is bent such that the front surface 21A of the flexible printed substrate 21 faces inward and the back surface 21B of the flexible printed substrate 21 faces outward. After the circuit board 20 is wound about one turn, the through hole 216 of the flexible printed substrate 21 is inserted through the protrusion 35. Accordingly, the flexible printed substrate 21 is positioned. At this time, portions near the through holes 215 and 216 of the flexible printed substrate 21 may be melted. In the state in which the circuit board 20 is wound, the circuit board 20 forms a polygonal shape (octagonal shape in the present example) with a contact portion between the wiring part 26 and the columnar member 33 as a vertex. As described above, in the positioned state, the wiring part 26 is in contact with the outside of the columnar member 33. The circuit component 24 (including the spring terminal 27) is disposed so as to face inward.

Next, the boundary portion 214A is bent to route the heat dissipation pad 214 from the peripheral edge of the base 31 toward the main surface 31B which is the bottom surface of the base 31. By inserting the routed heat dissipation pad 214 from the hole portion 32A, the heat dissipation pad 214 is guided to the main surface 31A side of the base 31 (see FIG. 12C).

Next, the battery 10 is disposed inside the columnar member 33. Specifically, the battery 10 is disposed inside the columnar member 33 such that the main surface 31A of the base 31 and the bottom surface (surface on which the positive electrode terminal 11 is not provided) of the battery 10 face each other. Accordingly, the bottom surface of the battery 10 and the main surface 31A of the base 31 are abutted against each other. As described above, since the heat dissipation pad 214 is disposed on the main surface 31A, the heat dissipation pad 214 is interposed between the bottom surface of battery 10 and the main surface 31A of the base 31. Since the heat dissipation pad 214 is in contact with the battery 10, heat generated from the circuit component 24C mounted on the flexible printed substrate 21 can be effectively released to the battery 10 (see FIG. 15B). When the battery 10 generates a large amount of heat, the heat generated from the battery 10 may be dissipated by the heat dissipation pad 214.

In the state where the battery 10 is disposed inside the columnar member 33, as illustrated in FIG. 15B, the spring terminal 27 is in contact with the circumferential side surface 13 of the battery 10, that is, the negative electrode terminal 12. Since a mounting location of the spring terminal 27 is connected to the negative electrode side of the positive and negative electrode external terminal 212 by a circuit pattern, the spring terminal 27 comes into contact with the circumferential side surface 13 of the battery 10, whereby the negative electrode external terminal side of the positive and negative electrode external terminal 212 and the negative electrode terminal 12 of the battery 10 are electrically connected.

Next, the boundary portion 210A is bent inward so that the positive electrode connection terminal 210 is disposed on the upper surface of the battery 10. The positive electrode connection terminal 210 comes into contact with the positive electrode terminal 11 provided on the upper surface of the battery 10, thereby making electrical connection. The positive electrode connection terminal 210 and the positive electrode terminal 11 may be connected by a conductive adhesive or the like.

Next, the wireless power supply portion 213 is disposed on the upper side of the positive electrode connection terminal 210 by bending the boundary portion 213A inward. When a magnetic flux generated at the time of wireless power supply to the battery 10 by the wireless power supply portion 213 reaches a metal exterior can surface of the battery 10, an eddy current is generated, and Joule heat is generated by electric resistance of metal. In order to prevent this, a magnetic sheet using a magnetic material may be disposed (for example, bonded) between the wireless power supply portion 213 and the positive electrode connection terminal 210 connected to the battery 10 to perform magnetic shielding.

Next, the boundary portion 211A is bent outward, whereby the output terminal arrangement portion 211 is bent outward (toward the reinforcing portion 25E). Accordingly, the positive and negative electrode external terminal 212 is disposed outside (see FIG. 12A, FIG. 13A, etc.).

The method of manufacturing the battery pack 100 described above is an example, and it goes without saying that the order of some steps may be changed.

According to an embodiment described above, the following effects can be obtained.

By disposing the circuit component on the peripheral surface of the battery, the height of the battery pack can be reduced.

There is provided the configuration in which a portion where the circuit component and the reinforcing portion are not provided, that is, the wiring part is in contact with the columnar member of the battery holder. As a result, when the circuit board is attached, mechanical stress due to an external impact on the battery pack 100 or a device main body to which the battery pack 100 is applied is applied to the wiring part, and substantially no mechanical stress can be applied to the circuit component mounting portion. Therefore, it is possible to suppress peeling of the circuit component and breakage of the reinforcing portion due to mechanical stress.

In the present embodiment, the circuit component faces inward, in other words, faces the circumferential side surface of the battery. This eliminates the need for a protective coating on the circuit component since the circuit component does not face outward. The circuit component generates heat during operation. In particular, a circuit component (for example, the circuit component 24C) that performs processing related to the wireless power supply portion generates a large amount of heat. As in the present embodiment, by making the circuit component face the circumferential side surface of the battery, the circuit component can be thermally coupled to the metal (battery can) forming the circumferential surface of the battery, and the heat generated from the circuit component can be effectively cooled.

Next, a second embodiment will be described. Note that, in the description of the second embodiment, the same or similar configurations in the above description are denoted by the same reference numerals, and redundant description is appropriately omitted. Further, the matters described in the first embodiment can be applied to the second embodiment unless otherwise specified.

A battery pack (battery pack 200) according to the second embodiment is different from that of the first embodiment in that the battery pack does not include the battery holder 30, and in addition, the circuit component 24 is disposed so as to face outward.

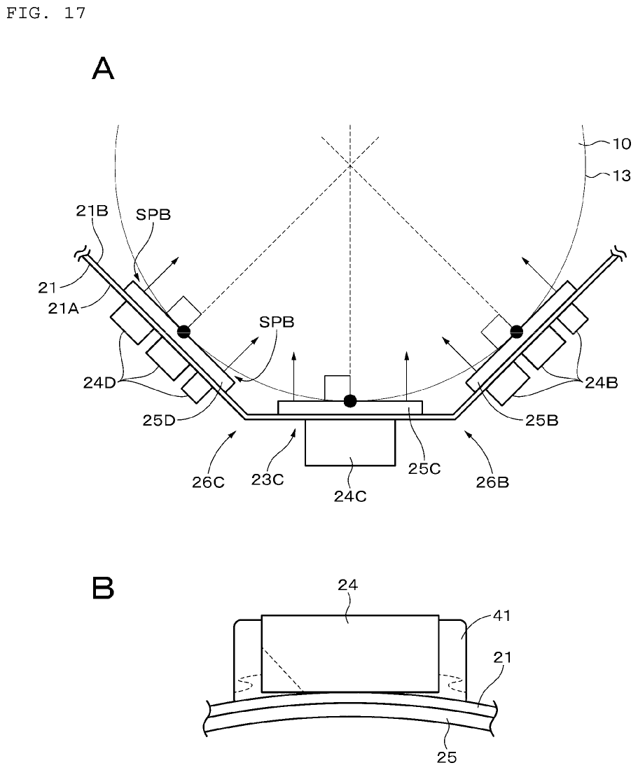

FIG. 16 is a diagram for describing a configuration example of a part of the battery pack 200. In the battery pack 200, a part of the circumferential side surface 13 of the battery 10 and a part of the reinforcing portion 25 are in contact with each other. In the example illustrated in FIG. 16, a part of the reinforcing portion 25B is in contact with a part of the circumferential side surface 13, a part of the reinforcing portion 25C is in contact with a part of the circumferential side surface 13, and a part of the reinforcing portion 25D is in contact with a part of the circumferential side surface 13. Although not illustrated, a part of the other reinforcing portion 25 is also in contact with a part of the circumferential side surface 13.

When the circuit board 20 is bent so as to be wound around the circumferential side surface 13 of the battery 10, the wiring part 26 is a portion to be bent. As a result, application of the mechanical stress at the time of bending to the circuit component 24 and the reinforcing portion 25 can be suppressed. Therefore, it is possible to suppress peeling of the circuit component 24 and breakage of the reinforcing portion 25 due to the mechanical stress. Similarly to the first embodiment, the height of the battery pack 200 can be reduced.

As described above, in the case of the present embodiment, since the circumferential side surface 13 of the battery 10, that is, the negative electrode portion of the battery 10 is in contact with the reinforcing portion 25, the reinforcing portion 25 contains an insulating material such as glass epoxy resin. Since the circuit component 24 is exposed to the outside, coating with epoxy resin or the like may be applied in order to protect the circuit component 24. As a result, the circuit component 24 can be protected from external stress, resistance to migration can be improved, and insulation can be secured.

Next, a third embodiment will be described. Note that, in the description of the third embodiment, the same or similar configurations in the above description are denoted by the same reference numerals, and redundant description is appropriately omitted. In addition, unless otherwise specified, the matters described in the first and second embodiments can be applied to the third embodiment.

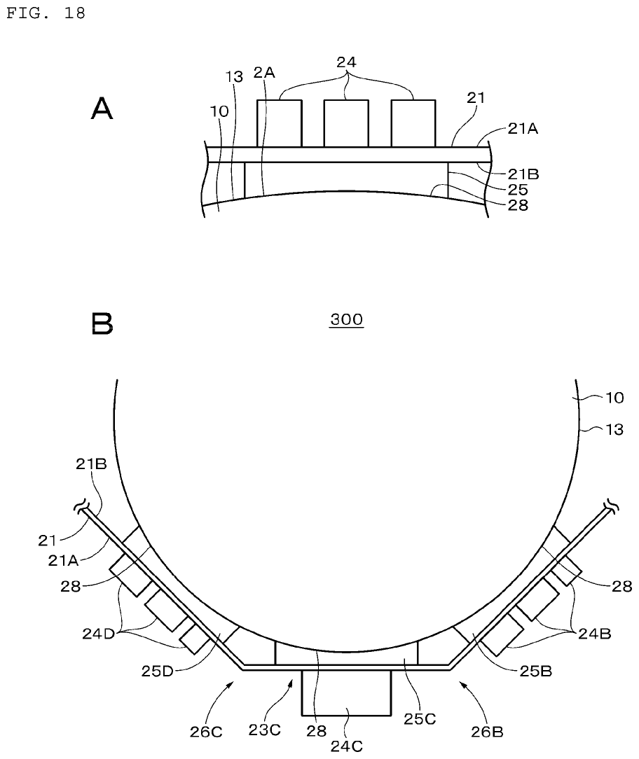

According to the configuration of the battery pack 200 according to the second embodiment described above, it is possible to suppress inconvenience caused by the mechanical stress when the flexible printed substrate 21 is bent. However, depending on the size and curvature of the battery 10, there is a possibility that inconveniences described below will occur. As illustrated in FIG. 17A, for example, when the circuit board 20 to which the flat plate-shaped reinforcing portion 25 is attached is attached along the circumferential side surface 13 of the cylindrical battery 10 having a large curvature, the reinforcing portion 25 and the circumferential side surface 13 are normally grounded with respect to the center of the battery 10. Thus, spaces SPB are generated on the left and right sides of the reinforcing portion 25. That is, when the circuit board 20 is wound along the circumferential side surface 13, the mechanical stress toward the center of the battery 10 is generated starting from a normal grounding portion (the contact portion between the reinforcing portion 25 and the circumferential side surface 13). Such mechanical stress may damage the reinforcing portion 25. As illustrated in FIG. 17B, a crack (shown as dotted lines in FIG. 17B) of the circuit component 24 and a crack of the solder mounting portion 41, which is a portion where the circuit component 24 is mounted with solder, become problems. The present embodiment is an embodiment in consideration of such points.

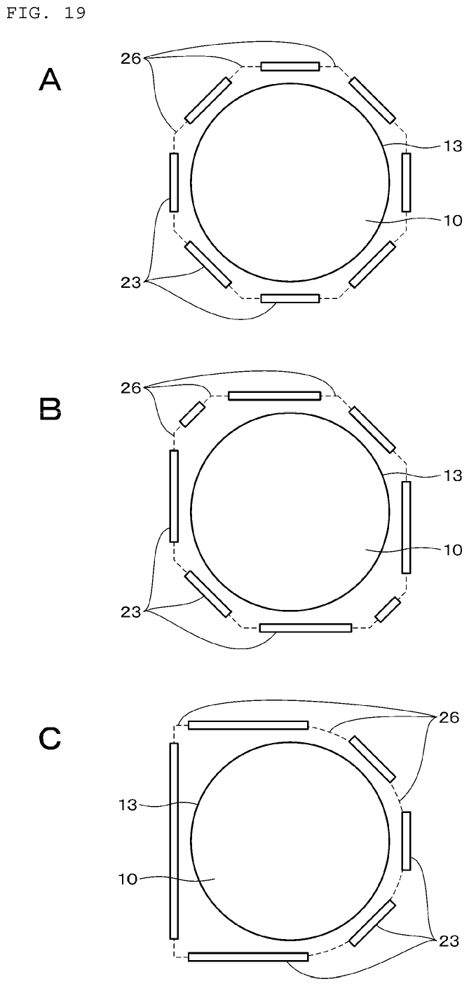

As illustrated in FIG. 18A, in the battery pack (battery pack 300) according to the present embodiment, the shape of the side of the reinforcing portion 25 (surface 28 in FIG. 18A) facing the circumferential side surface 13 of the battery 10 is substantially the same as the shape of a part of the facing circumferential side surface 13. For example, the curvature of a portion forming an arc on an end surface of the surface 28 is substantially the same (the same or an error is equal to or less than a certain value) as the curvature of the circumferential side surface 13. As a result, as illustrated in FIGS. 18A and 18B, the surface 28 and a part of the circumferential side surface 13 are in contact with each other throughout.

According to the third embodiment described above, since the surface 28 of the reinforcing portion 25 and a part of the circumferential side surface 13 are in contact with each other throughout, it is possible to suppress generation of mechanical stress on the left and right of the normal grounding portion. Therefore, it is possible to effectively suppress breakage of the reinforcing portion 25, peeling of the circuit component 24, and occurrence of cracks due to mechanical stress.

Although embodiments of the present disclosure have been described above, the contents of the present disclosure are not limited thereto, and it is possible to make various modifications based on the technical idea of the present disclosure according to an embodiment.

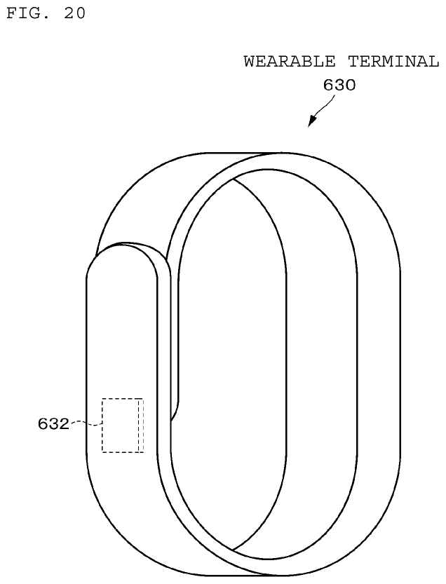

As illustrated in FIGS. 19A, 19B, and 19C, when the circuit component mounting portion 23 and the wiring part 26 included in the circuit board 20 are regarded as one set, and a plurality of sets having different area ratios are arranged, various polygons can be formed. As a result, it is possible to provide a battery pack that can be adapted to various sizes of batteries and various shapes of a housing in which the battery is housed.

A resin may be provided in the facing gap SPA described in the first embodiment. For example, the resin is provided in the facing gap SPA by curing a molten resin filled in the facing gap SPA. As a result, heat of the circuit component can be effectively transferred to the periphery (battery can) of the battery, and effective heat dissipation by the battery can becomes possible. In addition, since the resin is provided in the facing gap SPA, the deformation of the battery holder 30 and the like due to an external impact can be suppressed, so that the mechanical strength of the battery pack 100 can be improved. The circuit component 24 disposed in the facing gap SPA can be protected by resin.

The configuration of the battery pack can be appropriately changed according to an embodiment. For example, the battery pack may not include the wireless power supply portion or the heat dissipation pad. The battery pack may not include the positive and negative electrode output terminal, and the pattern of the copper foil corresponding to the positive and negative electrode output terminal may be exposed. The shape of the battery may be a shape other than a coin shape, such as a square shape. In order to secure rigidity (for example, rigidity of the through hole 215 and the flexible printed substrate 21 at the position of the through hole 215) of the flexible printed substrate, a reinforcing portion may be provided on a back surface of a portion where no circuit component is mounted. The circuit component mounting portion and the wiring part in the embodiment may include different flexible printed substrates.

The matters described in the above-described embodiments and modification example can be appropriately combined. Further, the materials, processes, and the like described in the embodiments are merely examples, and the contents of the present disclosure are not limited to the exemplified materials and the like.

The secondary battery according to an embodiment can be mounted on an electric tool, an electric vehicle, various electronic devices, or the like, or can be used for supplying electric power.

A specific application example will be described. For example, the secondary battery described above can be used as a power source of a wearable device having a function of a portable information terminal, that is, a so-called wearable terminal. Examples of the wearable terminal include a wristwatch-type terminal and a glasses-type terminal, but are not limited thereto. The wearable device also includes the hearable device described above.

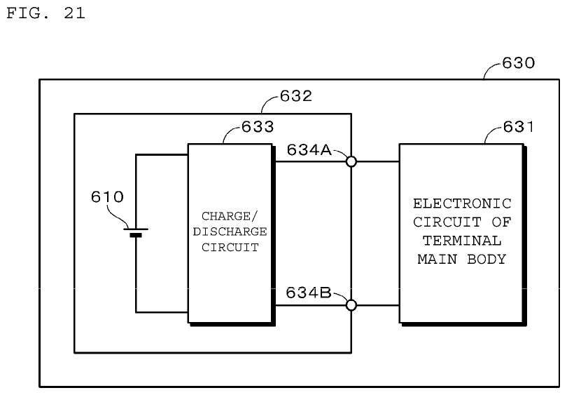

FIG. 20 illustrates an example of a wearable terminal with a built-in secondary battery. As shown in FIG. 20, a wearable terminal 630 according to the application example is a wristwatch-type terminal, and includes a secondary battery module 632 therein. The battery pack according to embodiment can be applied as the secondary battery module 632. The wearable terminal 630 can be worn and used by the user. The wearable terminal 630 may be a deformable flexible terminal.

As shown in FIG. 21, the wearable terminal 630 according to the application example includes an electronic circuit 631 of an electronic device main body and a secondary battery module 632. The secondary battery module 632 is electrically connected to the electronic circuit 631. The wearable terminal 630 has, for example, a configuration in which the secondary battery module 632 is detachable by the user. Note that, the configuration of the wearable terminal 630 is not limited thereto, and may have a configuration in which the secondary battery module 632 is built into the wearable terminal 630 so that the secondary battery module 632 cannot be removed from the wearable terminal 630 by the user.

When the secondary battery module 632 is charged, a positive electrode terminal 634A and a negative electrode terminal 634B of the secondary battery module 632 are connected to a positive electrode terminal and a negative electrode terminal of a charger (not illustrated), respectively. On the other hand, when the secondary battery module 632 is discharged (when the wearable terminal 630 is used), the positive electrode terminal 634A and the negative electrode terminal 634B of the secondary battery module 632 are connected to the positive electrode terminal and the negative electrode terminal of the electronic circuit 631, respectively.

The electronic circuit 631 includes, for example, a CPU, a peripheral logic unit, an interface unit, a storage unit, and the like, and controls the entire wearable terminal 630.

The secondary battery module 632 includes a secondary battery cell 610 (the battery 10 and the like in the embodiment) and a charge/discharge circuit 633. The charge/discharge circuit 633 is mounted on, for example, the flexible printed substrate 21 in the embodiment.

In the present application example, an example in which the present technology is applied to the secondary battery module 632 has been described, but the battery pack according to an embodiment may be mounted on the electronic circuit 631 of the electronic device main body.

### DESCRIPTION OF REFERENCE SYMBOLS

10: Battery
11: Positive electrode terminal
12: Negative electrode terminal
13: Circumferential side surface
20: Circuit board
21: Flexible printed substrate
23: Circuit component mounting portion
24: Circuit component
25: Reinforcing portion
30: Battery holder
33: Columnar member

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A battery pack comprising:
a battery including an electrode portion and having a cylindrical shape; and
a circuit board disposed on a circumferential side surface of the battery,
wherein the circuit board includes a circuit component mounting portion and a wiring part, the circuit component mounting portion includes a reinforcing portion, and the wiring part includes a flexible printed substrate.

2. The battery pack according to claim 1, wherein the circuit component mounting portion and the wiring part include an integrated flexible printed substrate.

3. The battery pack according to claim 1, wherein a plurality of the circuit component mounting portions are provided on the circuit board, and the plurality of circuit component mounting portions are coupled by the wiring part.

4. The battery pack according to claim 1, wherein the circuit component mounting portion and the electrode portion are electrically connected to each other.

5. The battery pack according to claim 1, wherein a part of the circumferential side surface of the battery and a part of the reinforcing portion are in contact with each other.

6. The battery pack according to claim 1, wherein the circuit component mounted on the circuit component mounting portion faces the circumferential side surface of the battery.

7. The battery pack according to claim 6, wherein a resin is provided in a facing gap between the circuit component and the circumferential side surface of the battery.

8. The battery pack according to claim 1, wherein the reinforcing portion includes at least one of a glass epoxy resin, a polyimide resin, and a metal plate.

9. The battery pack according to claim 1, further comprising a battery holder attached to the battery and including a resin.

10. The battery pack according to claim 9, wherein the battery holder includes a columnar member erected around the battery.

11. The battery pack according to claim 10, wherein the wiring part is in contact with an outside of the columnar member.

12. The battery pack according to claim 1, wherein a shape of a side of the reinforcing portion facing the circumferential side surface of the battery is substantially the same as a shape of a part of the facing circumferential side surface.

13. A wearable device comprising the battery pack according to claim 1.
